(19) United States
(12) Patent Application Publication
(10) Pub. No.: US 2008/0251123 A1
(43) Pub. Date: Oct. 16, 2008

(54) METHOD FOR PRODUCING A SOLAR CELL AND A SOLAR CELL PRODUCED ACCORDING TO SAID METHOD

(75) Inventors: Peter Fath, Konstanz (DE); Andre Kress, Konstanz (DE)

Correspondence Address: BAKER & DANIELS LLP;111 E. WAYNE STREET, SUITE 800, FORT WAYNE, IN, 46802, US

(73) Assignee: UNIVERSITAT KONSTANZ, Konstanz (DE)

(21) Appl. No.: 11/936,988

(22) Filed: Nov. 8, 2007

Related U.S. Application Data
(63) Continuation of application No. 10/363,001, filed on Oct. 20, 2003, now abandoned.

(30) Foreign Application Priority Data
Sep. 22, 2000 (DE) 10047556.6

(51) Int. Cl. H01L 31/00

(52) U.S. Cl. 136/258

(57) ABSTRACT

The problem posed by both conventional and novel crystalline silicon solar cells is the electrical isolation of layers doped with p and n conductivity types. The invention solves said problem in a simple and elegant manner. A masking paste is applied locally to at least one side of the silicon substrate and is subsequently dried. A doping material diffusion is then carried out, whereby the conductivity type of the doping material is in opposition to that of the base doping of the crystalline silicon substrate. In one of the subsequent production steps of the solar cell, the electric contacts are applied in such a way that at least one section of said contacts is isolated electrically from the rest of the contact by the masking paste. The masking paste thus allows an electrical isolation of the two external contacts of a solar cell by preventing the diffusion of one doping material using said paste. Other methods that achieve the same results are substantially more complex and expensive to use.

The invention concerns a method of fabricating a solar cell made of crystalline silicon and a crystalline-silicon solar cell fabricated by said method.

The object of this invention derives from the fact that both conventional and novel crystalline-silicon solar cells entail the problem of electrically isolating p- and n-doped layers. The present invention solves this problem in a manner that is simple, elegant and cost-effective for industrial production.

In effecting the electrical separation of p- and n-type layers, isolating separation alone is not enough to prevent short circuits. To avoid impairing the efficiency of the solar cell, the recombination velocity at the surface should not be too high at locations where n- and p-type regions border on each other.

Both can be achieved by means of the method presented hereinabove.

To prevent short circuits, in conventional crystalline-silicon solar cells the isolation of the pn junction is brought about by plasma-enhanced etching, by mechanical separation and by the use of lasers.

With more complex cell geometries involving stacked p- and n-type regions (such as, for example, EWT solar cells [J. M. Gee, W. K. Schubert, P. A. Basore, “Emitter Wrap-Through Solar Cells,” 23rd IEEE Photo. Spec. Conf., 1993, pp. 265-70], POWER solar cells [G. Willeke, P. Fath, “The POWER silicon solar cell concept,” 12th EC PVSEC, Amsterdam, 1994, Vol. 1, pp. 766-68; K. Faika et al., “Novel techniques to prevent edge isolation of silicon solar cells by avoiding leakage currents between the aluminum rear contact [sic],” Proc. 16th PVSEC, Glasgow, May 2000, in press; “Recent results in low cost back contact cells,” 16th PVSEC, Glasgow, 2000, in press]), isolation of the pn junction is achieved on the laboratory scale by:
plasma-enhanced etching
local removal of backside emitter (e.g. with a wafer saw or a laser)
use of dielectric layers as diffusion barriers, combined with photolithographic methods and printing techniques, as well as wet-chemical process steps,
codiffusion of evaporated contacts.

The disadvantages of the known solutions can be summarized as follows:
time-consuming and cost-intensive
some surface damage, leading to increased recombination velocity and thus lower efficiency for the cell.

Additional process steps to separate the p- and n-type regions, especially in the case of more complex cell geometries, are highly disadvantageous for industrial-scale production. The attendant cost has heretofore been one reason why, for example, back-contact solar cells have failed to gain acceptance in industrial production despite their many advantages with regard to modular circuitry.

### Physical Disadvantages

1. The creation of open, i.e. unpassivated, pn junctions when mechanical edge separation is performed
2. Surface damage caused by plasma-enhanced etching, leading to a detrimental effect on cell quality due to the associated increase in recombination
3. As a result of local mechanical milling to remove portions of the back of the silicon wafer, the space charge region is located directly on the surface of the cell. The noise levels introduced through the surface result in increased recombination (“junction edge effects”)→negative effects, especially on V_{oc} and FF.

The object of the present invention, i.e., the elimination of short-circuiting between mutually adjacent p- and n-type [noun missing], is achieved as follows.

A masking paste is applied locally to at least one side of the silicon substrate and is then dried. Dopant diffusion is then performed, the conduction type of the dopant being the opposite of that of the basic doping of the crystalline silicon substrate. In one of the ensuing steps in the fabrication of the solar cell, the electrical contacts are deposited in such a way that at least a portion of the contacts is separated electrically from the rest of the contacts by the masking paste.

To summarize, the method of the invention constitutes a substantial improvement in the simple fabrication of novel solar cells such as back-contact, bifacial and high-voltage solar cells. It will also be a major source of impetus in the production of future low-cost industrial solar cells using thin silicon wafers and the local back-contacting necessitated by that approach. Moreover, it can lead to simplification of the current method of fabricating conventional industrial solar cells.

The advantages of the invention are as follows:
Simplified processing→cost saving;
Good efficiency, due to very low surface recombination velocity

With the use of masking paste, the four process steps of the fabrication method used heretofore:
→full-area precipitation of a dielectric
→local deposition of an etching barrier
→process steps to partially remove the dielectric
→removal of the etching barrier
   are replaced by a single process step.

The solutions proposed in [1]¹ include substantially more, and more cost-intensive, process steps. The method described in [2] is suitable only for structured wafers. The technique of codiffusion preferably has to employ cost-intensive evaporation techniques; moreover, no further high-temperature step can be performed after codiffusion. ¹TRANSLATOR'S NOTE: Sic; there are no numbered references in our copy.

The invention was tested as follows.

The diffusion-barrier paste was applied to back-contact solar cells measuring 10×10 cm². The efficiency of these cells was found to be as high as 15.8% (independently confirmed by the EU Joint Research Center in Ispra, Italy). The solar-cell fabrication method was tested successfully with both Cz Si and multicrystalline Si. The invention is explained in more detail below with reference to two exemplary embodiments. Referring to the drawing:

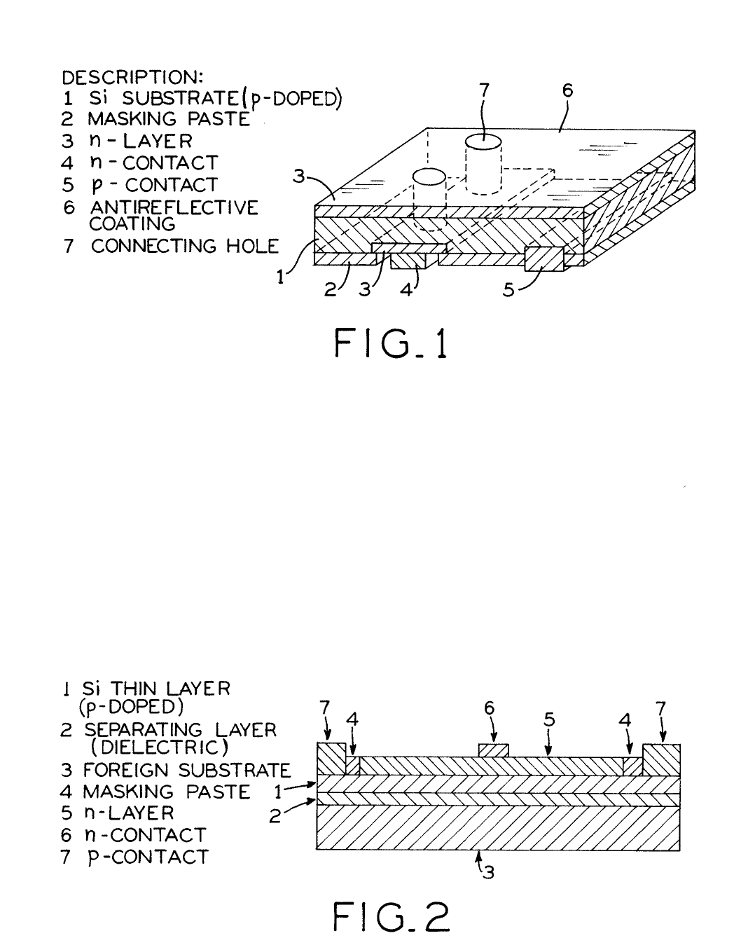

FIG. 1:

After etching and cleaning steps, the barrier paste (2) is deposited locally on a semiconductor wafer, preferably of crystalline silicon (1). The silicon wafer is then subjected to n⁺ diffusion. The n-type and p-type contacts (4 and 5) are then deposited. The cell depicted in the drawing is specifically one fabricated by the emitter wrap-through method, i.e., the front-side n-layer is connected by small holes to the n-contact on the back side of the cell.

FIG. 2:

A thin-layer cell grown on a foreign substrate (3) is provided locally on the front side with masking paste (4) and is then diffused. The contacts (6 and 7) are deposited on the front of the cell in such a way that the n-type and p-type contacts are isolated from each other by the masking paste.

1. A method of fabricating solar cells of crystalline silicon, characterized in that a masking paste is applied locally to at least one side of the silicon substrate and is then dried. Dopant diffusion is then performed, the conduction type of said dopant being the opposite of that of the basic doping of the crystalline silicon substrate. In one of the ensuing steps in the fabrication of the solar cell, the electrical contacts are deposited in such a way that at least a portion of the contacts is separated electrically from the rest of the contacts by the masking paste.

2. The method as recited in claim 1, characterized in that a masking paste is applied locally to both sides of said silicon substrate and is then dried.

3. The method as recited in claim 1, characterized in that through-holes are made in the portions of the surface not provided with masking paste.

4. The method as recited in claim 3, characterized in that said holes are made by laser.

5. The method as recited in claim 3, characterized in that said holes are made mechanically.

6. The method as recited in claim 1, characterized in that said masking paste is applied by a printing technique (preferably screen printing or rotary printing).

7. The method as recited in claim 1, characterized in that said masking paste contains oxides, preferably transition-metal oxides.

8. The method as recited in claim 1, characterized in that said silicon substrate is composed of a crystalline layer and a layer not made of silicon.

9. The method as recited in claim 1, wherein a type of doping on the back side of the cell is separated by the masking paste from the contact that contacts the other type of doping.
